(19) United States
(12) Patent Application Publication
(10) Pub. No.: US 2005/0238185 A1
(43) Pub. Date: Oct. 27, 2005

(54) Apparatus for reproduction of compressed audio data

(75) Inventor: Toshihiko Suzuki, Hamakita-shi (JP)

Correspondence Address: PILLSBURY WINTHROP SHAW PITTMAN LLP, 725 S. FIGUEROA STREET, SUITE 2800, LOS ANGELES, CA, 90017, US

(73) Assignee: Yamaha Corporation, Hamamatsu-shi (JP)

(21) Appl. No.: 11/111,081

(22) Filed: Apr. 21, 2005

(30) Foreign Application Priority Data
Apr. 26, 2004 (JP) 2004-129929

(51) Int. Cl. H03G 7/00

(52) U.S. Cl. 381/106

(57) ABSTRACT

An apparatus reproduces compressed sub-band samples into PCM audio data by use of a data processor that performs pitch-up processing or pitch-down processing in expansion of the compressed sub-band samples by way of inverse quantization, inverse scaling using scale factors, and synthesis, wherein the pitch-down processing uses all of the compressed sub-band samples, while the pitch-up processing discards prescribed sub-band samples whose frequencies are higher than a prescribed frequency (fs/2) from the sub-band samples. The reproduced PCM audio data are subjected to interpolation in synchronization with a clock frequency (fs) and a double clock frequency (2fs) respectively, wherein interpolated data synchronized with the clock frequency is output in respect of the pitch-down processing. A re-sampling circuit performs sampling on every other interpolated data synchronized with the double clock frequency so as to produce and output re-sampled data synchronized with the clock frequency in respect of the pitch-up processing.

### BACKGROUND OF THE INVENTION

1. Field of the Invention

This invention relates to apparatuses for reproduction of compressed audio data (e.g., compressed musical tone data), which are stored in digital storage media.

This application claims priority on Japanese Patent Application No. 2004-129929, the content of which is incorporated herein by reference.

2. Description of the Related Art

Recently, various formats and standards regarding compression of digital audio data such as MPEG, AUDIO MP3, AAC (i.e., MPEG-2 Advanced Audio Coding), and WMA have been developed. In the fields of karaoke devices and game devices, audio sounds (e.g., musical tones) are reproduced by expanding compressed audio data (e.g., compressed musical tone data) and are also subjected to pitch change processing such as pitch-up processing (for increasing reproduction velocities or reproduction rates of musical tones) and pitch-down processing (for decreasing reproduction velocities or reproduction rates of musical tones). For example, an original waveform (i.e., an analog audio waveform) shown in FIG. 2A is subjected to double pitch-up processing as shown in FIG. 2B in which a reproduced musical tone waveform is increased (or doubled) in reproduction velocity (or pitch).

FIG. 3A is a block diagram showing a compressed audio data generation circuit according to the MPEG/Audio standard, wherein reference numeral 10 designates a low-pass filter (LPF) for cutting off high-frequency components of an analog audio signal Au before compression, i.e., frequency components whose frequencies are higher than a half of sampling frequency fs. Reference numeral 11 designates an analog-to-digital converter (abbreviated in A/D) that performs sampling on the output of the LPF 10 at the sampling frequency fs so as to produce digital data.

The A/D converter 11 produces PCM audio data (where ‘PCM’ stands for ‘pulse-code modulation’), which are subjected to framing to produce a single frame per every 1152 samples in a framing circuit 1 and are than processed using two paths. In a first path, a sub-band analysis filtering bank 2 divides input data thereof into a plurality of sub-band data corresponding to thirty-two sub-bands each having the same bandwidth. Each sub-band data is subjected to down-sampling realizing 1/32 of the sampling frequency. A scale factor extraction and normalization circuit 3 handles a plurality of sub-band data (or sub-band samples) per one frame, wherein it detects a sample having a maximal absolute value, which is then quantized to produce a scale factor. All the sub-band samples are divided using the scale factor so as to produce values, which are then normalized within a prescribed range of ±1.

An auditory psychology analysis block 4 performs calculations on frequency spectra by using fast Fourier transform (FFT), whereby it produces masking thresholds with regard to sub-bands, that is, it produces allowable quantization noise power. Based on the output of the auditory psychology analysis block, a bit allocation block 5 determines a number of quantization bits per each sub-band by repetition loop processing under the limitation regarding the number of bits that can be used in one frame and that is determined based on a bit rate. A quantization block 6 performs quantization on sub-band data output from the scale factor extraction and normalization block 3 by use of the number of quantization bits, which is set with regard to each sub-band. A formatting block 7 performs multiplexing using ‘quantized’ sub-band samples, bit allocation information (that is provided with regard to each sub-band), and scale factors, thus producing a prescribed format of data, which is added with a header so as to produce a bit stream. FIG. 3B shows an example of the bit stream ‘B’.

FIG. 4 is a block diagram showing an example of a conventionally known apparatus for reproduction of compressed audio data, which expands compressed audio data. Specifically, the apparatus of FIG. 4 performs reproduction using pitch-down processing on audio data. Reference numeral 21 designates a ROM (i.e., a read-only memory) that stores compressed audio data; and reference numeral 22 designates a decoder that expands compressed audio data, which are read from the ROM 21, using a ‘normal’ velocity so as to reproduce PCM audio data before compression. Herein, the normal velocity is used to realize reproduction of compressed audio data without using pitch change processing. Reference numeral 23 designates an output buffer (i.e., a FIFO (first-in-first-out) memory) that temporarily stores ‘reproduced’ PCM audio data output from the decoder 22. Reference numeral 24 designates an interpolation circuit in which in the case of 1/2 pitch-down processing, PCM audio data output from the output buffer 23 are added with data created by linear interpolation so as to produce ‘interpolated’ data, which are then output therefrom in synchronization with a prescribed clock frequency (corresponding to the sampling frequency fs). Reference numeral 25 designates a digital-to-analog converter (abbreviated in D/A), which converts the output of the interpolation circuit 24 into analog audio signals.

FIG. 5 shows another example of the apparatus for reproduction of compressed audio data, which performs pitch-up processing in reproduction. Reference numeral 31 designates a ROM that stores compressed audio data; reference numeral 32 designates a decoder that expands compressed audio data, which are read from the ROM 31, using the double of the normal velocity so as to reproduce PCM audio data before compression; and reference numeral 33 designates an output buffer. Reference numeral 34 designates an interpolation circuit that reads PCM audio data from the output buffer 33 at a velocity corresponding to the double of the velocity of the aforementioned interpolation circuit 24 shown in FIG. 4, wherein in the case of double pitch-up processing as shown in FIG. 2C, it outputs PCM audio data without interpolation in synchronization with the double clock frequency 2 fs. In the case of the other pitch-up processing (e.g., 1.5-times pitch-up processing) whose pitch-up factor is greater than ‘1’ and less than ‘2’, PCM audio data are added with data created by linear interpolation so as to produce ‘interpolated’ data, which are then output in synchronization with the double clock frequency 2 fs. Reference numeral 35 designates a digital low-pass filter (LPF) that cuts off prescribed frequency components whose frequencies are higher than fs/2 from the output of the interpolation circuit 34. Reference numeral 36 designates a re-sampling circuit that performs sampling (or thin-out operation as shown in FIG. 2B) on every other data of the output of the LPF 35, which are output in synchronization with the double clock frequency 2 fs, so as to produce ‘re-sampled’ data, which are then output therefrom in synchronization with the clock frequency fs. Reference numeral 37 designates a digital-to-analog converter (abbreviated in D/A), which converts the output of the re-sampling circuit 36 to analog audio signals.

As described above, the apparatus for reproduction of compressed audio data can be designed to realize the pitch-down processing and pitch-up processing. In the case of pitch-down processing shown in FIG. 4, readout of the ROM 21 and expansion are performed at the normal velocity, whereby the original frequency spectrum (shown in FIG. 6A) output from the interpolation circuit 24 without pitch-down processing is changed as shown in FIG. 6B by way of pitch-down processing. That is, the pitch-down processing makes intervals between high-frequency components to be more concentrated so as to decrease the original pitch to a half without substantially changing the overall envelope of the frequency spectrum. That is, the pitch-down processing does not require the LPF 35 shown in FIG. 5.

In the case of double pitch-up processing, the original frequency spectrum (shown in FIG. 7A) output from the interpolation circuit 34 without pitch change processing are expanded double as shown in FIG. 7B in a higher-frequency direction. For this reason, when the output of the interpolation circuit 34 is directly subjected to re-sampling without using the LPF 35 and is then subjected to digital-to-analog conversion, so-called folding distortion may occur. In order to avoid the occurrence of folding distortion, it is necessary to insert the LPF 35 following the interpolation circuit 34, thus cutting off frequency components whose frequencies are higher than fs/2 as shown in FIG. 7C. FIG. 7D shows a frequency spectrum output from the re-sampling circuit 36.

As described above, the pitch-up processing adapted to the conventionally known apparatus for reproduction of compressed audio data requires a LPF, which in turn makes the overall circuit configuration more complicated; in other words, when the circuitry is realized using an LSI device, the overall chip size should be increased, which is not preferable.

Japanese Patent Application Publication No. 2002-49394 (corresponding to U.S. Pat. No. 6,752,110 B2) discloses a digital audio decoder in which level control is performed with respect to sub-bands so as to eliminate the necessity of using filters after decoding.

### SUMMARY OF THE INVENTION

It is an object of the invention to provide an apparatus for reproduction of compressed audio data, in which pitch-up processing is performed without using a low-pass filter.

An apparatus of this invention is designed to reproduce compressed sub-band samples into PCM audio data by way of a data processor that performs pitch-up processing or pitch-down processing in expansion of the compressed sub-band samples, wherein the pitch-down processing uses all of the sub-band samples, while the pitch-up processing discards prescribed sub-band samples whose frequencies are higher than a prescribed frequency (fs/2). An interpolation circuit performs interpolation on the reproduced PCM audio data so as to produce interpolated data, which are output therefrom in synchronization with a clock frequency (fs) in respect of the pitch-down processing and which are output therefrom in synchronization with a double clock frequency (2 fs) in respect of the pitch-up processing. A re-sampling circuit performs sampling on every other interpolated data synchronized with the double clock frequency so as to produce re-sampled data, which are output therefrom in synchronization with the clock frequency. A switch circuit selectively outputs the interpolated data synchronized with the clock frequency in respect of the pitch-down processing, while it selectively outputs the re-sampled data in respect of the pitch-up processing. These data are converted into analog audio signals.

Specifically, in the data processor, in respect of the pitch-down processing, all of the compressed sub-band samples are subjected to inverse quantization and inverse scaling using scale factors and are then synthesized together, and in respect of the pitch-up processing, the prescribed sub-band samples are discarded so that remaining sub-band samples within the compressed sub-band samples are selectively subjected to inverse quantization and inverse scaling using scale factors and are then synthesized together.

As described above, this invention is capable of performing pitch-up processing without using a low-pass filter (LPF), which is conventionally required. Thus, it is possible to simplify the circuit configuration and to reduce the overall chip size. In addition, this invention does not perform decoding on sub-band samples related to higher frequencies; hence, it is possible to reduce the power consumption in decoding.

### BRIEF DESCRIPTION OF THE DRAWINGS

These and other objects, aspects, and embodiments of the present invention will be described in more detail with reference to the following drawings, in which:

FIG. 1 is a block diagram showing the constitution of an apparatus for reproduction of compressed audio data in accordance with a preferred embodiment of the invention;

FIG. 2A shows an original analog audio waveform before processing;

FIG. 2B shows a waveform that is produced through double pitch-up processing and is output at a clock frequency fs;

FIG. 2C shows a waveform that is produced through double pitch-up processing and is output at a double clock frequency 2 fs;

FIG. 3A is a block diagram showing the constitution of a compressed audio data generation circuit;

FIG. 3B shows a format of one frame realized by the compressed audio data generation circuit shown in FIG. 3A;

FIG. 4 is a block diagram showing the constitution of an apparatus for reproduction of compressed audio data that performs pitch-down processing;

FIG. 5 is a block diagram showing the constitution of an apparatus for reproduction of compressed audio data that performs pitch-up processing;

FIG. 6A shows an original frequency spectrum adapted to the apparatus shown in FIG. 4;

FIG. 6B shows a frequency spectrum subjected to pitch-down processing in the apparatus shown in FIG. 4;

FIG. 7A shows an original frequency spectrum adapted to the apparatus shown in FIG. 5;

FIG. 7B shows a frequency spectrum that is expanded double in a higher-frequency direction;

FIG. 7C shows a frequency spectrum that is realized by cutting off frequency components whose frequencies are higher than fs/2 from the frequency spectrum shown in FIG. 7B; and

FIG. 7D shows a frequency spectrum output from a re-sampling circuit shown in FIG. 5.

### DESCRIPTION OF THE PREFERRED EMBODIMENT

This invention will be described in further detail by way of examples with reference to the accompanying drawings.

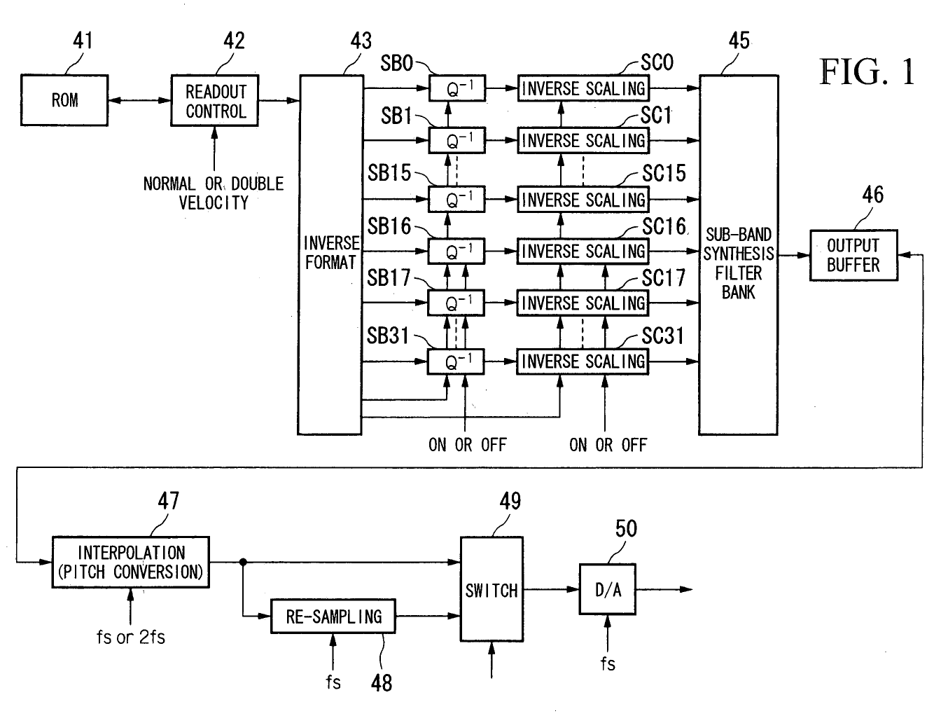

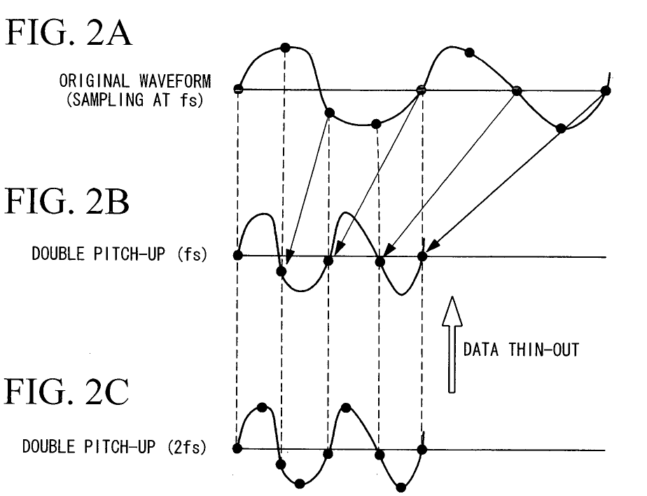

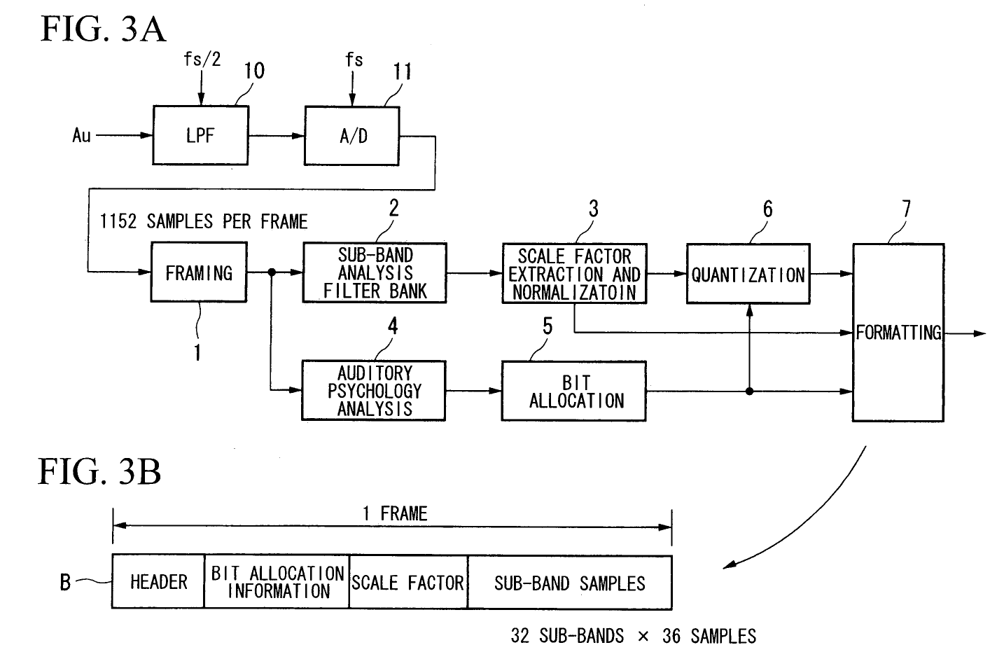

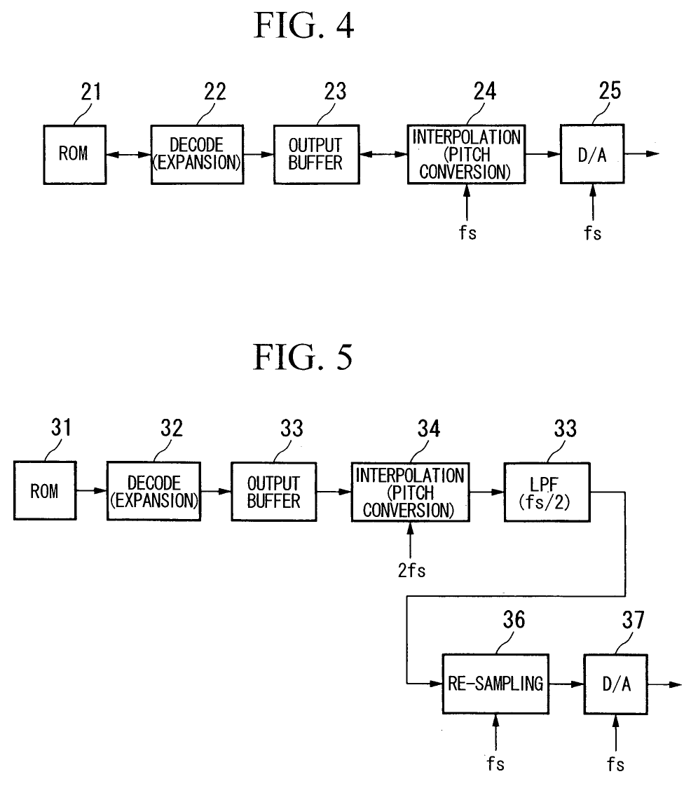

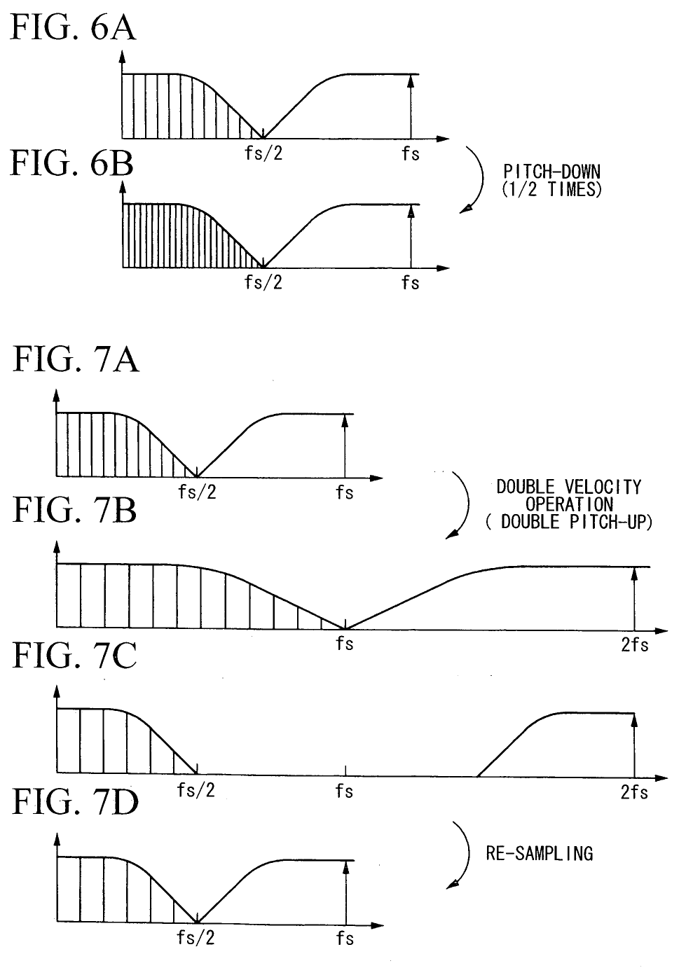

FIG. 1 is a block diagram showing the constitution of an apparatus for reproduction of compressed audio data in accordance with a preferred embodiment of the invention. Reference numeral 41 designates a ROM that stores compressed audio data (e.g., compressed musical tone data, see FIG. 3B) based on the MPED/Audio standard; and reference numeral 42 designates a read control circuit. The read control circuit 42 reads compressed audio data from the ROM 41, wherein it reads them at the normal velocity upon reception of a pitch-down instruction or a no-pitch-change instruction, whereas it reads them at the double of the normal velocity upon reception of a pitch-up instruction. Read compressed audio data are supplied to an inverse formatting circuit 43. The normal velocity indicates a read velocity adapted to reproduction of compressed audio data without pitch changes. Incidentally, pitch-up processing corresponds to high velocity reproduction, and pitch-down processing corresponds to low velocity reproduction.

The inverse formatting circuit 43 isolates sub-band samples, which are produced through quantization on every thirty-two sub-bands, bit allocation information, and scale factors from compressed audio data output from the read control circuit 42, whereby sub-band samples are respectively supplied to inverse quantization circuits SB0 to SB31 together with bit allocation information, and scale factors are respectively supplied to inverse scaling circuits SC0 to SC31.

The inverse quantization circuits SB0 to SB31 performs inverse quantization on sub-band samples by use of the bit allocation information, so that results are supplied to the inverse scaling circuits SC0 to SC31. There are provided thirty-two inverse quantization circuits SB0-SB31 in which the inverse quantization circuits SB16 to SB31 are related to high-frequency components and receive ON/OFF signals regarding pitch-down processing and pitch-up processing from an external control circuit (not shown). In the case of the pitch-down processing or upon issuance of a no-pitch-change instruction, the inverse quantization circuits SB16 to SB31 receive ON signals and are thus respectively activated. In the case of the pitch-up processing, the inverse quantization circuits SB16 to SB31 receive OFF signals and are thus respectively inactivated, so that they produce data ‘0’. In contrast to the inverse quantization circuits SB16 to SB31 that are switched over in operations in response to ON/OFF signals, the inverse quantization circuits SB0 to SB15 are normally activated.

Based on scale factors, the inverse scaling circuits SC0 to SC31 processes output data of the inverse quantization circuits SB0 to SB31 so as to restore their scales; then, results are supplied to the sub-band synthesis filter bank 45. There are provided thirty-two inverse scaling circuits SC0-SC31 in which similar to the inverse quantization circuits SB16 to SB31, the inverse scaling circuits SC16 to SC31 are related to high-frequency components and receive ON/OFF signals regarding pitch-down processing and pitch-up processing from the external control circuit (not shown). In the case of the pitch-down processing or upon issuance of a no-pitch-change instruction, the inverse scaling circuits SC16 to SC31 receive ON signals and are thus respectively activated. In the case of the pitch-up processing, the inverse scaling circuits SC16 to SC31 receive OFF signals and are thus respectively inactivated, so that they produce data ‘0’. In contrast to the inverse scaling circuits SC16 to SC31 that are switched over in operations in response to ON/OFF signals, the inverse scaling circuits SC0 to SC15 are normally activated.

The sub-band synthesis filter bank 45 synthesizes sub-band data output from the inverse scaling circuits SC0 to SC31 so as to reproduce ‘original’ PCM audio data before compression, which are then written into an output buffer 46. An interpolation circuit 47 reads PCM audio data from the output buffer 46, wherein data created by linear interpolation are added to PCM audio data, thus producing ‘interpolated’ data. Thus, in the case of the pitch-down processing or upon issuance of a no-pitch-change instruction, the interpolation circuit 47 outputs interpolated data in synchronization with the clock frequency fs. In the case of the pitch-up processing, the interpolation circuit 47 outputs interpolated data in synchronization with the double clock frequency 2 fs. A re-sampling circuit 48 performs sampling on every other data that are supplied thereto in synchronization with the double clock frequency 2 fs, thus outputting ‘re-sampled’ data in synchronization with the clock frequency fs. In the case of the pitch-down processing or upon issuance of a no-pitch-change instruction, a switch circuit 49 selects the output of the interpolation circuit 47. In the case of the pitch-up processing, the switch circuit 49 selects the output of the re-sampling circuit 48. A digital-to-analog converter (abbreviated in D/A) 50 converts data selected by the switch circuit 49 into analog audio signals.

According to the present embodiment, in the case of the pitch-down processing or upon issuance of a no-pitch-change instruction, all of the inverse quantization circuits SB0 to SB31 and all of the inverse scaling circuits SC0 to SC31 are activated, whereby compressed audio data read from the ROM 41 are reproduced into PCM audio data through normal expansion (i.e., conventionally known expansion), so that ‘reproduced’ PCM audio data are written into the output buffer 46. Then, PCM audio data written in the output buffer 46 are read out and are subjected to interpolation in the interpolation circuit 47, so that resultant data are output therefrom in synchronization with the clock frequency fs and are supplied to the D/A converter 50 via the switch circuit 49.

In the case of the pitch-up processing, the inverse quantization circuits SB16 to SB31 and the inverse scaling circuits SC16 to SC31 are respectively inactivated, whereby sub-band samples whose frequencies are higher than fs/2 are cut off, so that sub-band samples whose frequencies are lower than fs/2 are selectively supplied to the sub-band synthesis filter bank 45. As a result, ‘reproduced’ PCM audio data that are produced through synthesis in the sub-band synthesis filter bank 45 and are written into the output buffer 46 do not contain high-frequency components whose frequencies are higher than fs/2. Then, reproduced PCM audio data written in the output buffer 46 are subjected to interpolation in the interpolation circuit 47, whereby interpolated data are supplied to the re-sampling circuit 48 in synchronization with the double clock frequency 2 fs. The re-sampling circuit 48 performs sampling on every other data that are supplied thereto in synchronization with the double clock frequency 2 fs, thus producing re-sampled data, which are then supplied to the D/A converter 50 via the switch circuit 49 in synchronization with the clock frequency fs.

Incidentally, the present embodiment is specifically adapted to karaoke devices performing pitch-up processing and/or pitch-down processing on reproduced musical tones.

As this invention may be embodied in several forms without departing from the spirit or essential characteristics thereof, the present embodiment is therefore illustrative and not restrictive, since the scope of the invention is defined by the appended claims rather than by the description preceding them, and all changes that fall within metes and bounds of the claims, or equivalents of such metes and bounds are therefore intended to be embraced by the claims.

1. An apparatus for reproducing compressed sub-band samples into PCM audio data, said apparatus comprising:
a data processor for performing pitch-up processing or pitch-down processing in expansion of the compressed sub-band samples, which are thus reproduced into the PCM audio data in such a way that in the pitch-up processing, prescribed sub-band samples whose frequencies are higher than a prescribed frequency within the compressed sub-band samples are discarded;
an interpolation circuit for performing interpolation on the reproduced PCM audio data so as to produce interpolated data, which are output therefrom in synchronization with a first clock frequency in respect of the pitch-down processing and which are output therefrom in synchronization with a second clock frequency that is higher than the first clock frequency in respect of the pitch-up processing;
a re-sampling circuit for performing sampling on every other interpolated data that are supplied thereto in synchronization with the second clock frequency so as to produce re-sampled data that are output therefrom in synchronization with the first clock frequency; and
a switch circuit for selectively outputting the interpolated data supplied thereto from the interpolation circuit in synchronization with the first clock frequency in respect of the pitch-down processing and for selectively outputting the re-sampled data supplied thereto from the re-sampling circuit in respect of the pitch-up processing.

2. An apparatus according to claim 1, wherein the pitch-down processing corresponds to low-speed reproduction of the PCM audio data, and the pitch-up processing corresponds to high-speed reproduction of the PCM audio data.

3. An apparatus according to claim 1 further comprising a digital-to-analog circuit for converting the interpolated data or the re-sampled data selected by the switch circuit into analog audio signals.

4. An apparatus according to claim 1, wherein the second clock frequency is double of the first clock frequency.

5. An apparatus according to claim 1, wherein the prescribed frequency is a half of the first clock frequency.

6. An apparatus according to claim 1, wherein the data processor is designed such that in respect of the pitch-down processing, all of the compressed sub-band samples are subjected to inverse quantization and inverse scaling using scale factors and are then synthesized together, and in respect of the pitch-up processing, the prescribed sub-band samples are discarded so that remaining sub-band samples within the compressed sub-band samples are selectively subjected to inverse quantization and inverse scaling using scale factors and are then synthesized together.

7. A compressed audio data reproduction apparatus for reproduction of compressed audio data including compressed sub-band samples, which correspond to a plurality of sub-band samples, and compression information that is used to reproduce the compressed sub-band samples into original PCM audio data, said compressed audio data reproduction apparatus comprising:
a decoder for decoding the compressed sub-band samples respectively, wherein the decoder stops decoding a certain range of the compressed sub-band samples having relatively high frequencies in response to a pitch-up instruction designating a prescribed reproduction velocity that is higher than a normal reproduction velocity;
a synthesizer for synthesizing the sub-band samples that are decoded by the decoder; and
an interpolation and re-sampling device that interpolates prescribed data into synthesized data produced by the synthesizer, so that the synthesized data incorporating the prescribed data are subjected to re-sampling.
